(19) United States
(12) Patent Application Publication
(10) Pub. No.: US 2007/0173050 A1
(43) Pub. Date: Jul. 26, 2007

(54) Semiconductor device and method of manufacturing the same

(75) Inventors: Kazuhito Ichinose, Tokyo (JP); Akie Yutani, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 11/655,162

(22) Filed: Jan. 19, 2007

(30) Foreign Application Priority Data
Jan. 20, 2006 (JP) JP2006-012355

(51) Int. Cl. H01L 21/44

(52) U.S. Cl. 438/597

(57) ABSTRACT

A barrier metal film such as a TiN film is formed in a contact hole or a via hole. Then, a W nucleation film is formed on the barrier metal film by CVD that reduces WF₆ gas with B₂H₆ gas. Subsequently, a W plug is formed as a contact plug or a via plug on the W nucleation film by CVD.

### BACKGROUND OF THE INVENTION

1. Field of the Invention

This invention relates to semiconductor devices having a contact plug or a via plug, and methods of manufacturing the same.

2. Description of the Background Art

With recent miniaturization of semiconductor devices, it has been requested to reduce resistance values of a source and drain region and of a gate electrode in a MISFET (Metal Insulator Semiconductor Field Effect Transistor, e.g. a MOSFET: Metal Oxide Semiconductor FET). In order to reduce those resistance values, metal silicide is formed in a self-aligned manner on the surfaces of the source and drain region and gate electrode.

Ni (nickel) silicide is often adopted for the metal silicide. When Ni silicide is formed on the surface of the source and drain region, a contact plug that electrically connects upper wiring and the source and drain region is formed on the Ni silicide.

Ni silicide has low heat resistance. It is therefore required to form a barrier metal film on the inner walls of a contact hole for forming the contact plug by using a low-temperature film forming method and a material of low resistance. A TiN (titanium nitride) film formed by MOCVD (Metal Organic Chemical Vapor Deposition) is one example of barrier metal films formed with such method and material.

Formed on the TiN film made by MOCVD as a barrier metal film is a W (tungsten) plug as a contact plug body. This W plug is formed by CVD that reduces WF₆ (tungsten hexafluoride) gas with SiH₄ (silane) gas.

Further in a semiconductor device, a via plug is formed on an upper wiring layer of Al (aluminum) and Cu (copper) to be electrically connected to the upper wiring layer through a barrier film. A TiN film formed by MOCVD, for example, is again adopted for a barrier metal film on the inner walls of a via hole for forming the via plug. Then, a W plug is formed as a via plug body by CVD that reduces WF₆ gas with SiH₄ gas.

Japanese Patent Application Laid-Open No. 8-264530 (1996) and National Publication of Translation No. 2001-525491 constitute prior art to this invention.

The barrier metal film such as the TiN film formed by MOCVD has high resistivity. This means a thick barrier metal film increases resistance values of the contact plug and via plug. Therefore, the barrier metal films in the contact plug and via plug need to be formed thin.

When the W plug is formed on the barrier metal film by CVD that reduces WF₆ gas with SiH₄ gas, however, fluorine components damage the TiN film which is a thin barrier metal film, to sometimes reach as far as the Ni silicide (for a contact plug) and the Al wiring (for a via plug) under the barrier metal film. A sufficiently thick barrier metal film will be able to block the damage caused by fluorine components, but a barrier metal cannot be formed thick in order to reduce the resistance values of the contact plug and via plug, as described above.

Particularly in a so-called shared contact plug structure where a contact plug is connected to both a source and drain region and a gate electrode, fluorine components may reach a polysilicon gate electrode exposed in a portion where a sidewall insulating film has been cut through a barrier metal film, also affecting a resistance value of the gate electrode.

As for a via plug, a via hole sometimes exposes a portion not covered by a barrier film of an upper wiring layer due to mask misalignment. When that happens, fluorine components may reach the exposed portion of the upper wiring layer through a barrier metal film, also affecting a resistance value of the upper wiring layer.

### SUMMARY OF THE INVENTION

It is an object of this invention to provide a semiconductor device having a contact plug or via plug formed from tungsten and a method of manufacturing the same that are less likely to affect a layer under a thin barrier metal film in a contact plug or via plug.

In a first aspect of the invention, a method of manufacturing a semiconductor device includes the following steps (a) to (f). Namely, the method includes the steps of: (a) forming a MISFET (Metal Insulator Semiconductor Field Effect Transistor) on a surface of a semiconductor substrate, said MISFET including a source and drain region, a gate insulating film, and a gate electrode; (b) forming an insulating film to cover said surface of said semiconductor substrate and said MISFET; (c) forming a contact hole in said insulating film such that at least part of said source and drain region and at least part of a side surface of said gate electrode are exposed in said contact hole; (d) forming a barrier metal film in said contact hole; (e) forming a W (tungsten) nucleation film on said barrier metal film by CVD (Chemical Vapor Deposition) that reduces WF₆ (tungsten hexafluoride) gas with B₂H₆ (diborane) gas; and (f) forming a W (tungsten) plug on said W nucleation film by CVD with WF₆ gas, to bury said W plug in said contact hole.

According to this method, the W nucleation film is formed on the barrier metal film by CVD that reduces WF₆ gas with B₂H₆ gas, and then the W plug is formed on the W nucleation film by CVD. This causes a reduction in fluorine concentration in the W nucleation film, which prevents fluorine from eroding the barrier metal film and the layer thereunder. Accordingly, a method of manufacturing the same can be realized that is less likely to affect a layer under a thin barrier metal film in a contact plug of the so-called shared structure.

In a second aspect of the invention, a method of manufacturing a semiconductor device includes the following steps (a) to (g). Namely, the method includes the steps of: (a) forming a wiring layer above a semiconductor substrate; (b) forming a barrier film on said wiring layer; (c) forming an insulating film to cover said wiring layer and said barrier film; (d) forming a via hole in said insulating film such that at least part of said barrier film is exposed in said via hole, said via hole being formed such that at least part of a side surface of said wiring layer is also exposed in said via hole; (e) forming a barrier metal film in said via hole; (f) forming a W (tungsten) nucleation film on said barrier metal film by CVD (Chemical Vapor Deposition) that reduces WF₆ (tungsten hexafluoride) gas with B₂H₆ (diborane) gas; and (g) forming a W (tungsten) plug on said W nucleation film by CVD with WF₆ gas, to bury said W plug in said via hole.

According to this method, the W nucleation film is formed on the barrier metal film by CVD that reduces WF₆ gas with B₂H₆ gas, and then the W plug is formed on the W nucleation film by CVD. This causes a reduction in fluorine concentration in the W nucleation film, which prevents fluorine from eroding the barrier metal film and the layer thereunder. Accordingly, a method of manufacturing the same can be realized that is less likely to affect a layer under a thin barrier metal film in a via plug.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 5 illustrate sectional views of a process of a method of manufacturing a semiconductor device according to a first preferred embodiment of this invention;

FIG. 6 illustrates a sectional view of the semiconductor device according to the first preferred embodiment;

FIG. 7 illustrates a semiconductor device manufactured by a conventional method of manufacturing a semiconductor device;

FIG. 8 illustrates the semiconductor device manufactured by the method of manufacturing a semiconductor device according to the first preferred embodiment;

FIG. 9 is a graph demonstrating the effect of the semiconductor device and the method of manufacturing the same according to the first preferred embodiment;

FIG. 10 is a graph demonstrating the relationship between a barrier metal film thickness and resistivity of the semiconductor device according to the first preferred embodiment;

FIGS. 11 to 15 illustrate sectional views of a process of a method of manufacturing a semiconductor device according to a second preferred embodiment of this invention;

FIG. 16 illustrates a sectional view of the semiconductor device according to the second preferred embodiment;

FIG. 17 illustrates another sectional view of the semiconductor device according to the second preferred embodiment; and

FIG. 18 is a graph demonstrating the effect of the semiconductor device and the method of manufacturing the same according to the second preferred embodiment.

### DESCRIPTION OF THE PREFERRED EMBODIMENTS

### First Preferred Embodiment

This embodiment is directed at a semiconductor device and a method of manufacturing the same, in which a W nucleation film is formed on a barrier metal film by CVD that reduces WF₆ gas with B₂H₆ gas, and then a W plug is formed as a contact plug on the W nucleation film by CVD.

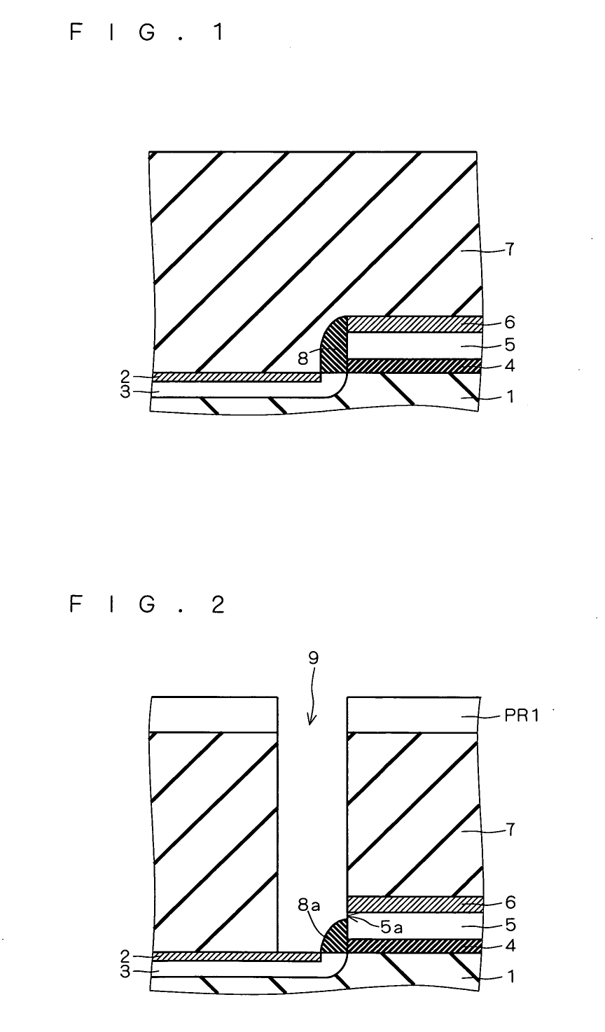

FIGS. 1 to 5 illustrate sectional views of a process of the method of manufacturing the semiconductor device according to this embodiment. FIG. 6 illustrates a sectional view of the semiconductor device according to this embodiment.

First, as shown in FIG. 1, a MISFET including a source and drain region 3, source and drain silicide 2, a gate insulating film 4, a gate electrode 5, gate silicide 6, and a sidewall insulating film 8 is formed on the surface of a semiconductor substrate 1 such as a silicon substrate. The source and drain silicide 2, the gate insulating film 4, the gate electrode 5, the gate silicide 6, and the sidewall insulating film 8 are nickel silicide, a silicon oxide film, a polysilicon film, nickel silicide, and a silicon nitride film, respectively, for example.

The gate insulating film 4 and the gate electrode 5 are formed by forming a laminated film of a silicon oxide film and a polysilicon film on the semiconductor substrate 1 with CVD (Chemical Vapor Deposition) and the like, and patterning the laminated film with photolithography techniques and etching techniques. The sidewall insulating film 8 is formed by forming a silicon nitride film with CVD and the like to cover the surface of the semiconductor substrate 1 and the MISFET, and then performing anisotropic etching on the silicon nitride film.

The source and drain region 3 is formed by implanting impurities in an appropriate area on the surface of the semiconductor substrate 1. The source and drain silicide 2 and the gate silicide 6 are formed by forming a nickel film to cover the surface of the semiconductor substrate 1 and the MISFET, performing a silicidation process on the nickel film by heat treatment, and removing unreacted portions of the nickel film. After that, an interlayer insulating film 7 is formed by CVD and the like to cover the surface of the semiconductor substrate 1 and the MISFET. The interlayer insulating film 7 is a silicon oxide film, for example.

Next, as shown in FIG. 2, a photoresist PR1 is formed on the interlayer insulating film 7. The photoresist PR1 is then patterned by being selectively exposed and developed. Then, the interlayer insulating film 7 is dry etched with the patterned photoresist PR1 as a mask. As a result, a contact hole 9 for forming a contact plug that electrically connects an upper wiring layer (described later) and the source and drain region 3 is formed in the interlayer insulating film 7. Subsequently, the photoresist PR1 is removed by plasma ashing and the like.

The contact plug according to this embodiment has a so-called shared contact plug structure that is connected to both the source and drain region 3 and the gate electrode 5. And in the contact hole 9, at least part of the source and drain region 3 (which includes the source and drain silicide 2 on its surface) and at least part of a side surface 5a of the gate electrode 5 (which includes the gate silicide 6 on its surface) are exposed. In the course of the etching of the interlayer insulating film 7, the sidewall insulating film 8 is also etched to some extent, to be deformed to a shrunk sidewall insulating film 8a.

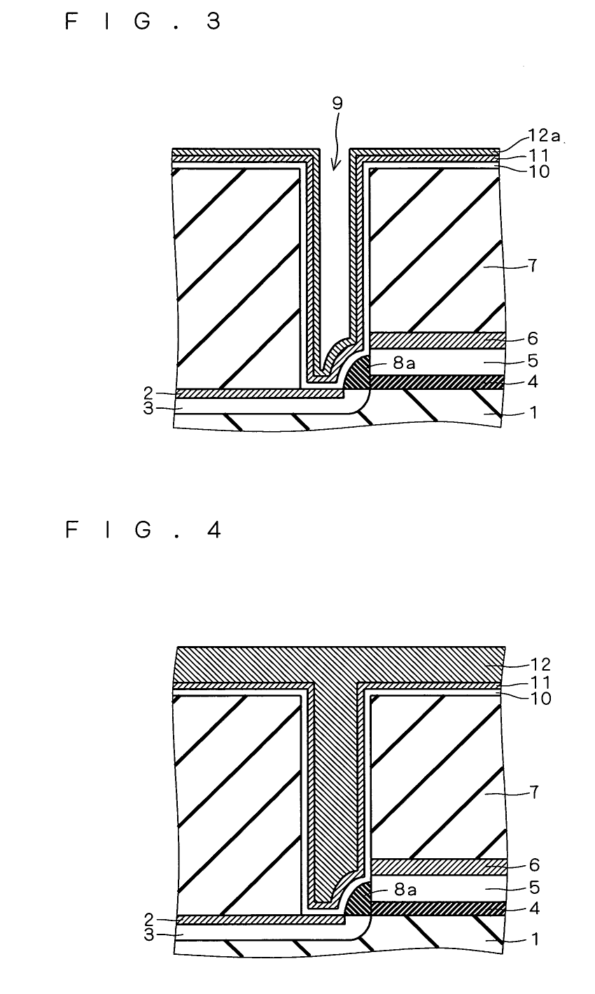

Next, as shown in FIG. 3, barrier metal films 10 and 11 are formed in the contact hole 9. Prior processing is performed before forming the barrier metal films 10 and 11, such as removing oxide films on the surfaces of the source and drain silicide 2 and the gate silicide 6, and removing etching residues from the formation of the contact hole 9.

The barrier metal film according to this embodiment is a laminated film of a Ti film 10 and a TiN film 11. The TiN film 11 is formed by MOCVD at a film forming temperature of not more than 550° C., for example. The laminated film of the Ti film 10 and the TiN film 11 is 10 nm thick, for example. The barrier metal film may be formed as a laminated film of a WN (tungsten nitride) film and a W (tungsten) film, instead of the laminated film of the Ti film 10 and the TiN film 11. In such case, the WN film is again formed by MOCVD. Alternatively, the barrier metal film may be formed only from a TiN film or a WN film. In such case, the TiN film or WN film is again formed by MOCVD.

Then, a W (tungsten) nucleation film 12a is formed on the TiN film 11 serving as a barrier metal film. The W nucleation film 12a is formed by CVD that reduces WF₆ (tungsten hexafluoride) gas with B₂H₆ (diborane) gas and, more specifically, formed by ALD (Atomic Layer Deposition). The W nucleation film 12a is a W film that becomes a growth nucleus when forming a W plug, which is described next.

Next, as shown in FIG. 4, a W (tungsten) plug 12 is formed on the W nucleation film 12a, to be buried in the contact hole 9. The W plug 12 may be formed by CVD with WF₆ gas and, more specifically, formed by CVD that reduces WF₆ gas with SiH₄ (silane) gas. Alternatively, the W plug 12 may be formed by CVD that reduces WF₆ gas with B₂H₆ gas. The W plug 12 may be formed in the same chamber of the CVD device used for the formation of the W nucleation film 12a, or in a separate chamber.

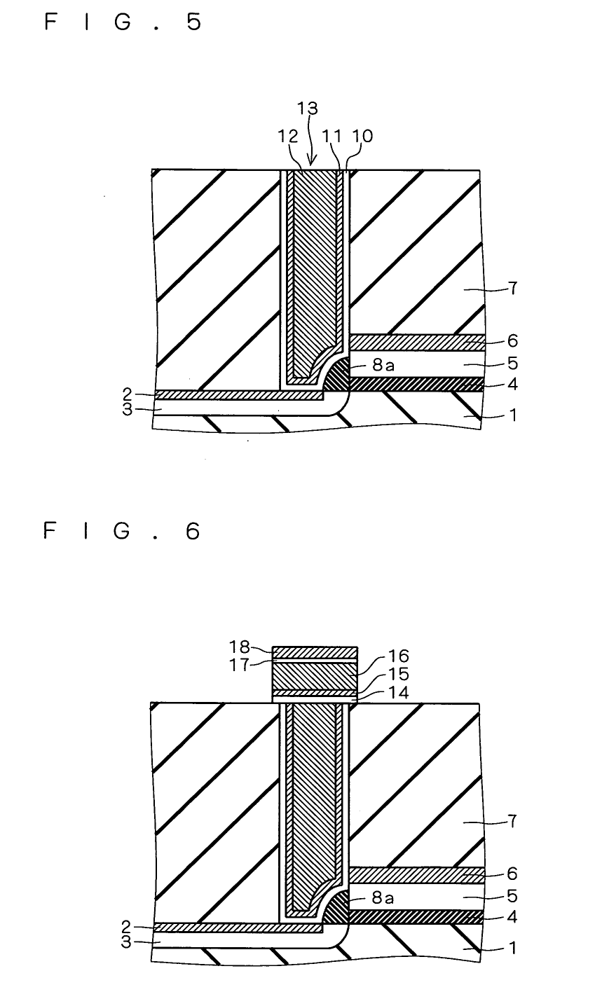

Next, as shown in FIG. 5, the Ti film 10, the TiN film 11, and the W plug 12 on the interlayer insulating film 7 are removed by CMP (Chemical Mechanical Polishing) and the like, to expose the interlayer insulating film 7. As a result, a plug top 13 is also exposed.

Next, as shown in FIG. 6, an upper wiring layer to be connected to the plug top 13 is formed by film forming techniques such as sputtering, and photolithography techniques and etching techniques, to complete the semiconductor device according to this embodiment. The upper wiring layer may be formed as a laminated film of a Ti film 14, a TiN film 15, and an Al or Cu film 16. Formed on the surface of this laminated film is another laminated film of a Ti film 17 and a TiN film 18 as a barrier film. When the Al or Cu film 16 is formed from a Cu film, the upper wiring layer has a damascene structure.

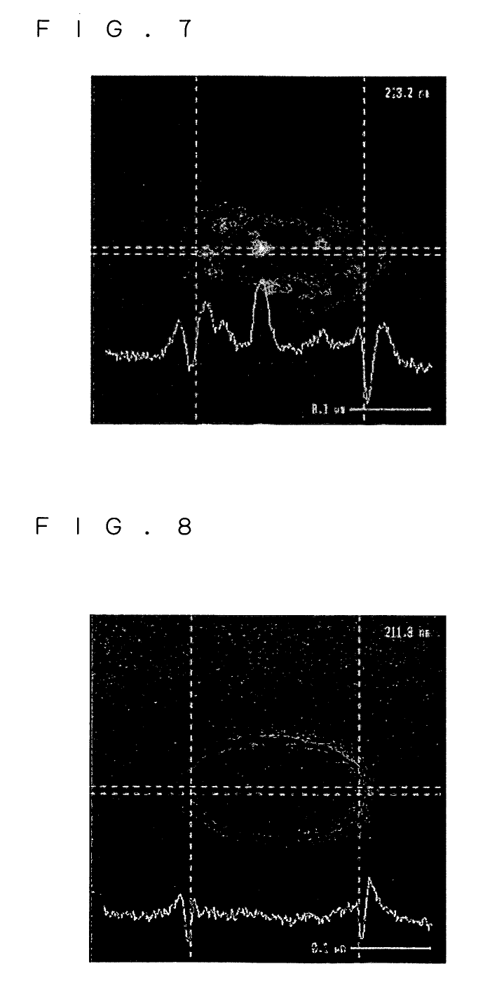

FIG. 7 illustrates a semiconductor device manufactured by a conventional method of manufacturing a semiconductor device. Namely, FIG. 7 shows an electron microscope photograph of a plug top when a W plug is formed on a TiN film serving as a barrier metal film by CVD that reduces WF₆ gas with SiH₄ gas. FIG. 8 shows an electron microscope photograph of the plug top 13 in the semiconductor device manufactured by the method according to this embodiment.

As can be seen from comparing FIGS. 7 and 8, a thin barrier metal film (blackened portion) around a W plug (elliptical portion) is damaged by fluorine components and deformed in FIG. 7, whereas the thin barrier metal film around the W plug is not too damaged in FIG. 8.

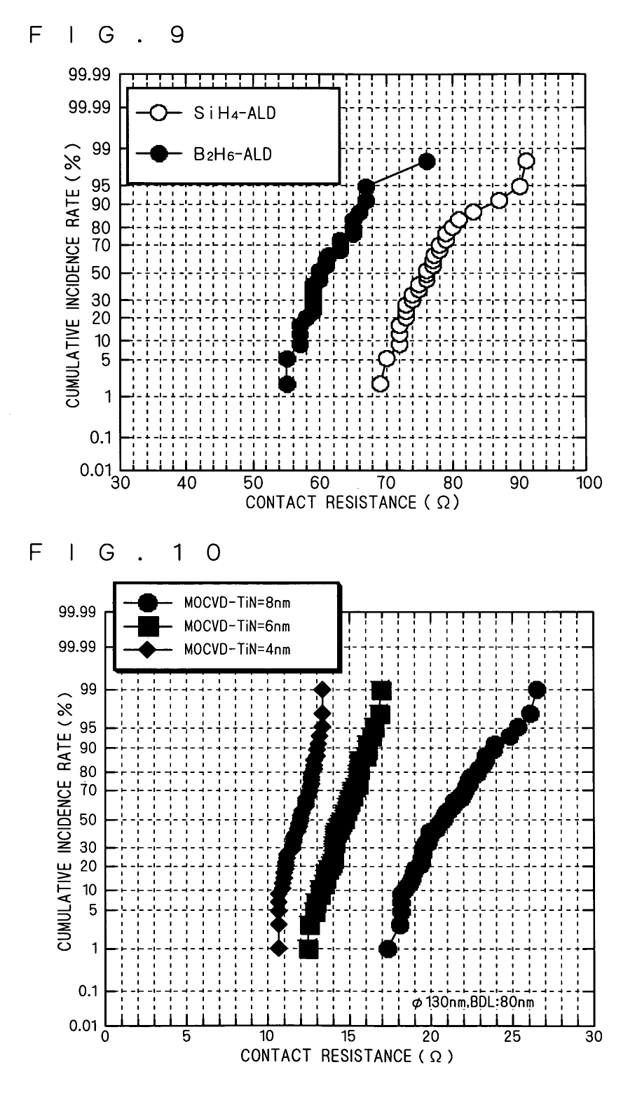

FIG. 9 is a graph demonstrating the effect of the semiconductor device and the method of manufacturing the same according to this embodiment. The horizontal axis of the graph represents contact resistance of the W plug (in ohm), and the vertical axis represents a cumulative incidence rate of a plurality of samples (in percent). FIG. 9 is a semilogarithmic graph.

The measurement results indicated by a symbol “◯” in FIG. 9 were obtained when both the W nucleation film and the W plug were formed by the conventional CVD that reduces WF₆ gas with SiH₄ gas. The measurement results indicated by a symbol “” in FIG. 9 were obtained when the W nucleation film 12a was formed by CVD that reduces WF₆ gas with B₂H₆ gas, and then the W plug 12 was formed by CVD that reduces WF₆ gas with SiH₄ gas, as in this embodiment.

As can be appreciated from the graph shown in FIG. 9, the contact resistance value of the W plug is reduced by approximately twenty percent than a conventional value when the W nucleation film 12a is formed by CVD that reduces WF₆ gas with B₂H₆ gas, as in this embodiment. This is attributed to the fact that fluorine concentration in the W nucleation film 12a is reduced by adopting the B₂H₆ gas reduction, making it difficult for fluorine to erode the barrier metal film and the layer thereunder. Likewise, it is considered that the excellently formed barrier metal film shown in FIG. 8 was obtained due to the reduction in fluorine concentration in the W nucleation film 12a, which leads to less damage by fluorine.

FIG. 10 is a graph demonstrating the relationship between the thickness of the TiN film 11 serving as a barrier metal film and the resistance value of the W plug 12. The horizontal axis of the graph represents contact resistance of the W plug (in ohm), and the vertical axis represents a cumulative incidence rate of a plurality of samples (in percent). FIG. 10 is also a semilogarithmic graph.

As can be appreciated from FIG. 10 showing the results with thicknesses of 4 nm, 6 nm and 8 nm, respectively, the thinner the TiN film 11 formed by MOCVD, the lower the resistance value of the W plug 12. The inventors of this application conducted experiments that revealed that a desired thickness for the TiN film 11 formed by MOCVD is not more than 10 nm.

In the semiconductor device and the method of manufacturing the same according to this embodiment, the W nucleation film 12a is formed on the barrier metal film by CVD that reduces WF₆ gas with B₂H₆ gas, and then the W plug 12 is formed on the W nucleation film 12a by CVD. This causes a reduction in fluorine concentration in the W nucleation film 12a, which prevents fluorine from eroding the barrier metal film and the layer thereunder. Accordingly, a semiconductor device and a method of manufacturing the same can be realized that are less likely to affect a layer under a thin barrier metal film in a contact plug of the so-called shared structure.

Also in the semiconductor device and the method of manufacturing the same according to this embodiment, the barrier metal film is formed from one of a TiN film, a WN film, a laminated film of a TiN film and a Ti film, and a laminated film of a WN film and a W film, with the TiN film and WN film being formed by MOCVD. This allows the barrier metal film to be formed thin.

Further in the semiconductor device and the method of manufacturing the same according to this embodiment, the W nucleation film 12a is formed by ALD. This allows the W nucleation film 12a to be formed thin.

Still further in the semiconductor device and the method of manufacturing the same according to this embodiment, the W plug 12 on the W nucleation film 12a can also be formed by CVD that reduces WF₆ gas with B₂H₆ gas. Therefore, a semiconductor device and a method of manufacturing the same can be realized that are less likely to affect a layer under a barrier metal film.

### Second Preferred Embodiment

This embodiment is directed at a modified example of the semiconductor device and the method of manufacturing the same according to the first preferred embodiment. In this embodiment, a via plug is additionally provided to be connected to the upper wiring layer of the first preferred embodiment. Again, the via plug is formed by forming a W nucleation film on a barrier metal film by CVD that reduces WF₆ gas with B₂H₆ gas, and then forming a W plug on the W nucleation film by CVD.

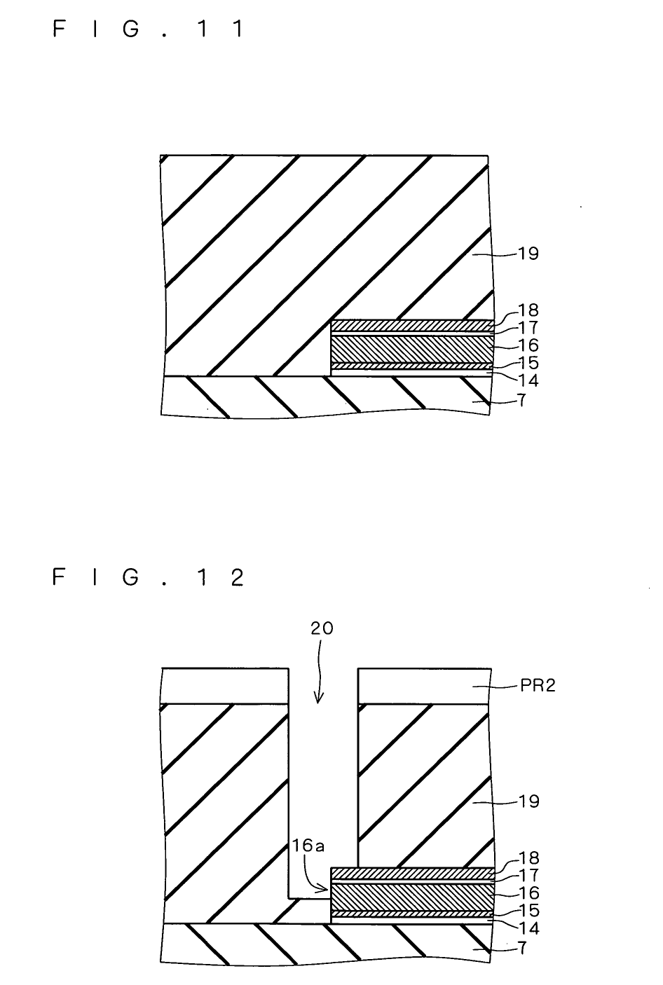

FIGS. 11 to 15 illustrate sectional views of a process of the method of manufacturing the semiconductor device according to this embodiment. FIG. 16 illustrates a sectional view of the semiconductor device according to this embodiment.

First, as shown in FIG. 11, an interlayer insulating film 19 is formed by CVD and the like to cover the upper wiring layer (the laminated film of the Ti film 14, the TiN film 15 and the Al or Cu film 16) and the barrier film (the laminated film of the Ti film 17 and the TiN film 18) on the interlayer insulating film 7 formed above the semiconductor substrate 1, and the surface of the interlayer insulating film 7. The interlayer insulating film 19 is a silicon oxide film, for example.

Next, as shown in FIG. 12, a photoresist PR2 is formed on the interlayer insulating film 19. The photoresist PR2 is then patterned by being selectively exposed and developed. Then, the interlayer insulating film 19 is dry etched with the patterned photoresist PR2 as a mask. As a result, a via hole 20 for forming a via plug that electrically connects the upper wiring layer (the laminated film of the Ti film 14, the TiN film 15 and the Al or Cu film 16) and another upper wiring layer (described later) is formed in the interlayer insulating film 19. Subsequently, the photoresist PR2 is removed by plasma ashing and the like.

The via plug according to this embodiment is assumed to be a so-called “bowing” via plug that is connected to not only the surface but a side surface of the upper wiring layer (the laminated film of the Ti film 14, the TiN film 15 and the Al or Cu film 16). The “bowing” is a phenomenon that occurs frequently in the course of manufacture as semiconductor devices become miniaturized. And in the via hole 20, at least part of the barrier film (the laminated film of the Ti film 17 and the TiN film 18) and at least part of a side surface 16a of the upper wiring layer (the laminated film of the Ti film 14, the TiN film 15 and the Al or Cu film 16) are exposed.

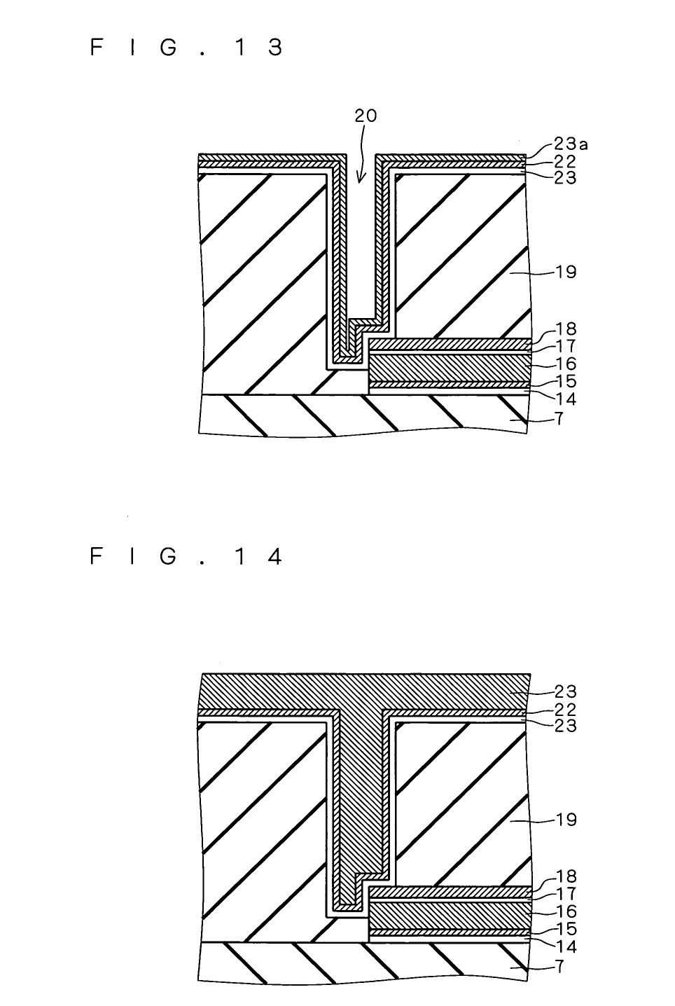

Next, as shown in FIG. 13, barrier metal films 21 and 22 are formed in the via hole 20. Prior processing is performed before forming the barrier metal films 21 and 22, such as removing oxide films on the side surface of the upper wiring layer (the laminated film of the Ti film 14, the TiN film 15 and the Al or Cu film 16) and the surface of the barrier film (the laminated film of the Ti film 17 and the TiN film 18), and removing etching residues from the formation of the contact hole 20.

The barrier metal film according to this embodiment is a laminated film of a Ti film 21 and a TiN film 22. The TiN film 22 is formed by MOCVD at a film forming temperature of not more than 450° C., for example. The laminated film of the Ti film 21 and the TiN film 22 is 10 nm thick, for example. The barrier metal film may be formed as a laminated film of a WN (tungsten nitride) film and a W (tungsten) film, instead of the laminated film of the Ti film 21 and the TiN film 22. In such case, the WN film is again formed by MOCVD. Alternatively, the barrier metal film may be formed only from a TiN film or a WN film. In such case, the TiN film or WN film is again formed by MOCVD.

Then, a W (tungsten) nucleation film 23a is formed on the TiN film 22 serving as a barrier metal film. The W nucleation film 23a is formed by CVD that reduces WF₆ (tungsten hexafluoride) gas with B₂H₆ (diborane) gas and, more specifically, formed by ALD. The W nucleation film 23a is a W film that becomes a growth nucleus when forming a W plug, which is described next.

Next, as shown in FIG. 14, a W (tungsten) plug 23 is formed on the W nucleation film 23a, to be buried in the via hole 20. The W plug 23 may be formed by CVD with WF₆ gas and, more specifically, formed by CVD that reduces WF₆ gas with SiH₄ (silane) gas. Alternatively, the W plug 23 may be formed by CVD that reduces WF₆ gas with B₂H₆ gas. The W plug 23 may be formed in the same chamber of the CVD device used for the formation of the W nucleation film 23a, or in a separate chamber.

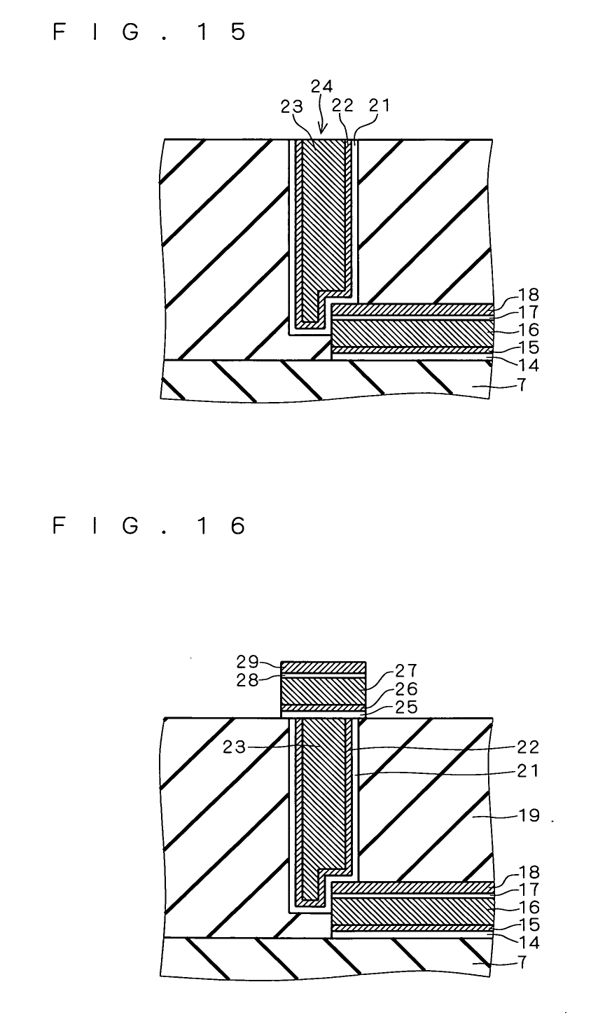

Next, as shown in FIG. 15, the Ti film 21, the TiN film 22, and the W plug 23 on the interlayer insulating film 19 are removed by CMP and the like, to expose the interlayer insulating film 19. As a result, a plug top 24 is also exposed.

Next, as shown in FIG. 16, another upper wiring layer to be connected to the plug top 24 is formed by film forming techniques such as sputtering, and photolithography techniques and etching techniques, to complete the semiconductor device according to this embodiment. The another upper wiring layer may be formed as a laminated film of a Ti film 25, a TiN film 26, and an Al or Cu film 27. Formed on the surface of this laminated film is yet another laminated film of a Ti film 28 and a TiN film 29 as a barrier film. When the Al or Cu film 27 is formed from a Cu film, the another upper wiring layer has a damascene structure.

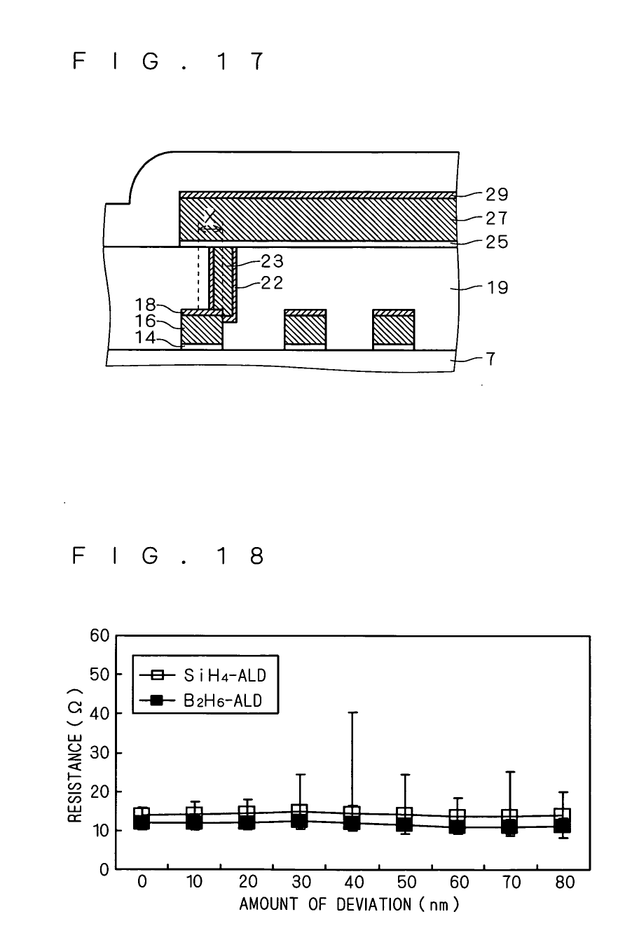

FIG. 17 illustrates another sectional view of the semiconductor device shown in FIG. 16 according to this embodiment. As shown in FIG. 17, the degree of “bowing” of the via plug according to this embodiment is determined by the amount of deviation X from the original position where the via plug is supposed to be formed.

FIG. 18 is a graph demonstrating the effect of the semiconductor device and the method of manufacturing the same according to this embodiment. The vertical axis of the graph represents contact resistance of the W plug (in ohm) and a cumulative incidence rate (magnitude of which is indicated by the length of an I-shaped rod) of a plurality of samples, and the horizontal axis represents the amount of deviation X in FIG. 17 (in nm).

The measurement results indicated by a symbol “□” in FIG. 18 were obtained when both the W nucleation film and the W plug were formed by the conventional CVD that reduces WF₆ gas with SiH₄ gas. The measurement results indicated by a symbol “▪” in FIG. 18 were obtained when the W nucleation film 23a was formed by CVD that reduces WF₆ gas with B₂H₆ gas, and then the W plug 23 was formed by CVD that reduces WF₆ gas with SiH₄ gas, as in this embodiment.

As can be appreciated from the graph shown in FIG. 18, the contact resistance value of the W plug is reduced than a conventional value when the W nucleation film 23a is formed by CVD that reduces WF₆ gas with B₂H₆ gas, as in this embodiment. This is attributed to the fact that fluorine concentration in the W nucleation film 23a is reduced by adopting the B₂H₆ gas reduction, making it difficult for fluorine to erode the barrier metal film and the layer thereunder.

In the semiconductor device and the method of manufacturing the same according to this embodiment, the W nucleation film 23a is formed on the barrier metal film by CVD that reduces WF₆ gas with B₂H₆ gas, and then the W plug 23 is formed on the W nucleation film 23a by CVD. This causes a reduction in fluorine concentration in the W nucleation film 23a, which prevents fluorine from eroding the barrier metal film and the layer thereunder. Accordingly, a semiconductor device and a method of manufacturing the same can be realized that are less likely to affect a layer under a thin barrier metal film in a so-called bowing via plug.

Also in the semiconductor device and the method of manufacturing the same according to this embodiment, the barrier metal film is formed from one of a TiN film, a WN film, a laminated film of a TiN film and a Ti film, and a laminated film of a WN film and a W film, with the TiN film and WN film being formed by MOCVD. This allows the barrier metal film to be formed thin.

Further in the semiconductor device and the method of manufacturing the same according to this embodiment, the W nucleation film 23a is formed by ALD. This allows the W nucleation film 23a to be formed thin.

Still further in the semiconductor device and the method of manufacturing the same according to this embodiment, the W plug 23 on the W nucleation film 23a can also be formed by CVD that reduces WF₆ gas with B₂H₆ gas. Therefore, a semiconductor device and a method of manufacturing the same can be realized that are less likely to affect a layer under a barrier metal film.

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing a semiconductor device, comprising the steps of:
(a) forming a MISFET (Metal Insulator Semiconductor Field Effect Transistor) on a surface of a semiconductor substrate, said MISFET including a source and drain region, a gate insulating film, and a gate electrode;
(b) forming an insulating film to cover said surface of said semiconductor substrate and said MISFET;
(c) forming a contact hole in said insulating film such that at least part of said source and drain region and at least part of a side surface of said gate electrode are exposed in said contact hole;
(d) forming a barrier metal film in said contact hole;
(e) forming a W (tungsten) nucleation film on said barrier metal film by CVD (Chemical Vapor Deposition) that reduces WF₆ (tungsten hexafluoride) gas with B₂H₆ (diborane) gas; and
(f) forming a W (tungsten) plug on said W nucleation film by CVD with WF₆ gas, to bury said W plug in said contact hole.

2. The method of manufacturing a semiconductor device according to claim 1, wherein
said barrier metal film is formed from one of a TiN (titanium nitride) film, a WN (tungsten nitride) film, a laminated film of a TiN film and a Ti (titanium) film, and a laminated film of a WN film and a W (tungsten) film, and
said TiN film and said WN film are formed by MOCVD (Metal Organic Chemical Vapor Deposition).

3. The method of manufacturing a semiconductor device according to claim 1, wherein
said W nucleation film is formed by ALD (Atomic Layer Deposition).

4. The method of manufacturing a semiconductor device according to claim 1, wherein
said W plug is also formed by CVD that reduces WF₆ gas with B₂H₆ gas.

5. A method of manufacturing a semiconductor device, comprising the steps of:
(a) forming a wiring layer above a semiconductor substrate;
(b) forming a barrier film on said wiring layer;
(c) forming an insulating film to cover said wiring layer and said barrier film;
(d) forming a via hole in said insulating film such that at least part of said barrier film is exposed in said via hole, said via hole being formed such that at least part of a side surface of said wiring layer is also exposed in said via hole;
(e) forming a barrier metal film in said via hole;
(f) forming a W (tungsten) nucleation film on said barrier metal film by CVD (Chemical Vapor Deposition) that reduces WF₆ (tungsten hexafluoride) gas with B₂H₆ (diborane) gas; and
(g) forming a W (tungsten) plug on said W nucleation film by CVD with WF₆ gas, to bury said W plug in said via hole.

6. The method of manufacturing a semiconductor device according to claim 5, wherein
said barrier metal film is formed from one of a TiN (titanium nitride) film, a WN (tungsten nitride) film, a laminated film of a TiN film and a Ti (titanium) film, and a laminated film of a WN film and a W (tungsten) film, and
said TiN film and said WN film are formed by MOCVD (Metal Organic Chemical Vapor Deposition).

7. The method of manufacturing a semiconductor device according to claim 5, wherein
said W nucleation film is formed by ALD (Atomic Layer Deposition).

8. The method of manufacturing a semiconductor device according to claim 5, wherein
said W plug is also formed by CVD that reduces WF₆ gas with B₂H₆ gas.

9. A semiconductor device manufactured by the method of manufacturing a semiconductor device according to claim 1.

10. A semiconductor device manufactured by the method of manufacturing a semiconductor device according to claim 5.
